(19) United States
(12) Patent Application Publication
(10) Pub. No.: US 2006/0152991 A1
(43) Pub. Date: Jul. 13, 2006

(54) Non-volatile memory storage of fuse information

(76) Inventors: Hyun-Duk Cho, Gyeonggi-do (KR); Jin-Yub Lee, Seoul (KR); Jin-Kook Kim, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/259,951

(22) Filed: Oct. 26, 2005

(30) Foreign Application Priority Data
Oct. 26, 2004 (KR) 2004-85753

(51) Int. Cl. G11C 17/18

(52) U.S. Cl. 365/225.7

(57) ABSTRACT

A fuse-free circuit may include a NAND flash memory cell, and a switch to turn on or off in response to data stored in the NAND flash memory cell. The fuse-free circuit may be embodied in a semiconductor device that also includes an adjustable circuit coupled to the switch. The adjustable circuit may be structured to emulate the No_Cut or Cut operation of a fuse in response to the on or off state of the switch.

### CROSS-REFERENCE TO RELATED APPLICATIONS

This U.S. non-provisional patent application claims priority under 35 U.S.C. § 119 from Korean Patent Application 2004-85753 filed on Oct. 26, 2004, the entire contents of which are hereby incorporated by reference.

### BACKGROUND

Semiconductor memory devices use direct current (DC) at various voltage levels. The DC voltage levels are generated by a DC voltage generator in the memory device. Typically, the target DC voltage levels to be used by the memory device are determined during the design phase. Ideally, the actual voltages generated by the DC voltage generator should be identical to the target voltages.

However, due to process variations in the manufacturing phase, the actual voltages generated are typically different from the target values. Therefore, laser fuses are used to adjust the actual voltages to the target values without making a mask revision. Laser fuse methods allow a manufacturer to trim the actual voltages to the target values by selectively cutting one or more laser fuses connected to the DC voltage generator. Circuits used for adjusting the actual voltage using the laser fuses are referred to as trim circuits.

Laser trim circuits may also be used to repair a memory device having defective memory cells that are encountered during the manufacturing process. Extra memory cells called redundancy cells are used to repair a device having defective memory cells. When a memory cell is defective, a repair circuit substitutes a redundancy memory cell for the defective memory cell by selectively cutting one or more fuses in a laser fuse box.

However, the use of laser fuses in trim or repair circuits introduces its own set of problems. First, in order to use a laser fuse, an additional mask is required. Second, since semiconductor memory chips are continuously becoming more miniaturized, manufacturing processes for the chips are becoming finer to the point that laser fuses are no longer suitable. That is, because there is a limit to reducing the size of laser fuses, the use of laser fuses is ineffective in reducing the size of a memory chip. Third, in order to cut a laser fuse, several Electrical Die Sorting (EDS) test procedures and test equipment are needed. Fourth, after a memory device is mounted in a package, fuse information cannot be varied. And finally, once a laser fuse is cut, it cannot be reconnected.

### SUMMARY

In one exemplary embodiment according to the inventive principles of this patent disclosure, a fuse-free circuit may include a NAND flash memory cell, and a switch to turn on or off in response to data stored in the NAND flash memory cell.

In another exemplary embodiment according to the inventive principles of this patent disclosure, a fuse-free semiconductor device may include a NAND flash memory device to store fuse information, a switch to turn on or off electrically in response to the fuse information, and an adjustable circuit coupled to the switch. The adjustable circuit may be structured to emulate the No_Cut or Cut operation of a fuse in response to the on or off state of the switch.

In another exemplary embodiment according to the inventive principles of this patent disclosure, a fuse-free non-volatile memory device may include a non-volatile memory cell array to store fuse information, a switch to be turned on or off electrically in response to the fuse information; and an internal adjustable circuit coupled to both ends of the switch. The non-volatile memory device may also include a data output controller to receive the fuse information from the memory cell array and output the fuse information in response to a clock signal, and a latch circuit to receive and latch the fuse information from the data output controller and fuse information and apply the fuse information to the switch.

In another exemplary embodiment according to the inventive principles of this patent disclosure, a method may include storing fuse information in a NAND flash memory cell, electrically turning a switch on or off in response to the fuse information, and emulating the No_Cut or Cut operation of a fuse in response to the on or off state of the switch.

### BRIEF DESCRIPTION OF THE DRAWINGS

FIG. 1 is a block diagram showing an embodiment of a fuse-free circuit according to according to the inventive principles of this patent disclosure.

FIG. 2 is a circuitry diagram of another embodiment of a fuse-free circuit according to the inventive principles of this patent disclosure.

FIG. 3 is a block diagram showing an embodiment of a fuse-free semiconductor device according to the inventive principles of this patent disclosure.

FIG. 4 is a block diagram showing an embodiment of a fuse-free non-volatile memory device according to the inventive principles of this patent disclosure.

FIG. 5 is a block diagram showing an embodiment of a fuse-free non-volatile memory device according to the inventive principles of this patent disclosure.

FIGS. 6 through 8 are block diagrams showing example embodiments of latch circuits according to the inventive principles of this patent disclosure.

FIGS. 9A through 9F are circuitry diagrams showing example embodiment of switches according to the inventive principles of this patent disclosure.

### DETAILED DESCRIPTION

Preferred embodiments according to the inventive principles of this patent disclosure will be described below in more detail with reference to the accompanying drawings. The inventive principles may, however, be embodied in different forms and should not be constructed as limited to the embodiments set forth herein. Rather, these embodiments are provided so that this disclosure will be thorough and complete, and will fully convey the scope of the inventive principles to those skilled in the art.

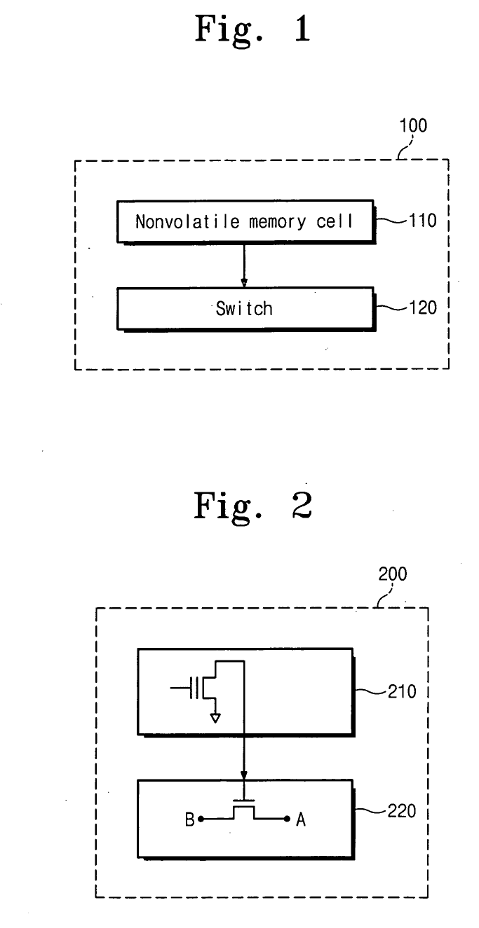

FIG. 1 is a block diagram showing an embodiment of a fuse-free circuit according to the inventive principles of this patent disclosure. Referring to FIG. 1, the fuse-free circuit 100 includes a non-volatile memory cell 110 and a switch 120. The non-volatile memory cell 110 stores fuse information. A switch 120 is electrically turned on or off in response to the fuse information. For example, when data stored in the non-volatile memory cell 110 is logic value “1”, the switch 120 is turned on. This is analogous to as a fuse in a No_Cut state. In contrast, when data stored in the non-volatile memory cell 110 is logic value “0”, the switch 120 is turned off. This is analogous to as a fuse in a Cut state. As described above, the fuse-free circuit 100 according to the inventive principles of this patent disclosure may produce the same effect as the Cut and No_Cut states of a fuse by using a switch coupled to a non-volatile memory cell.

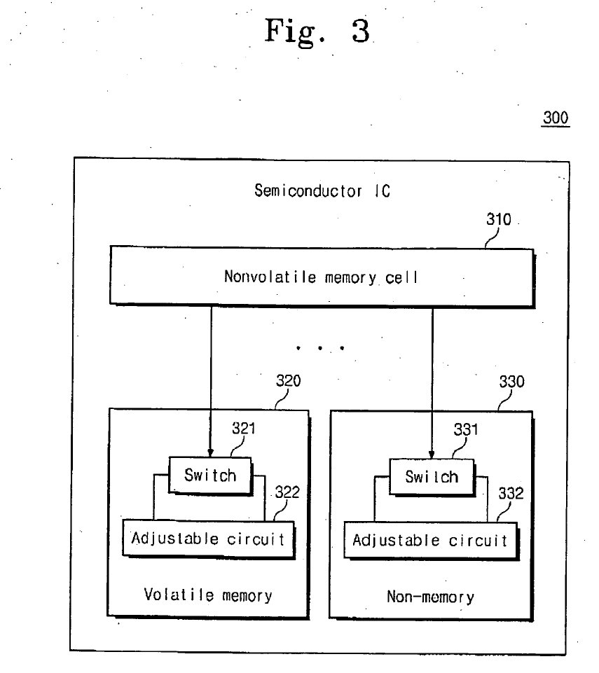

FIG. 2 is a circuitry diagram of an embodiment of a fuse-free circuit 200 according to the inventive principles of this patent disclosure showing some possible implementation details which may be applied to the circuit of FIG. 1. The fuse-free circuit 200 includes a flash memory cell 210 and an NMOS transistor 220. The NMOS transistor 220 is electrically turned on or off in response to data stored in the flash memory cell 210.

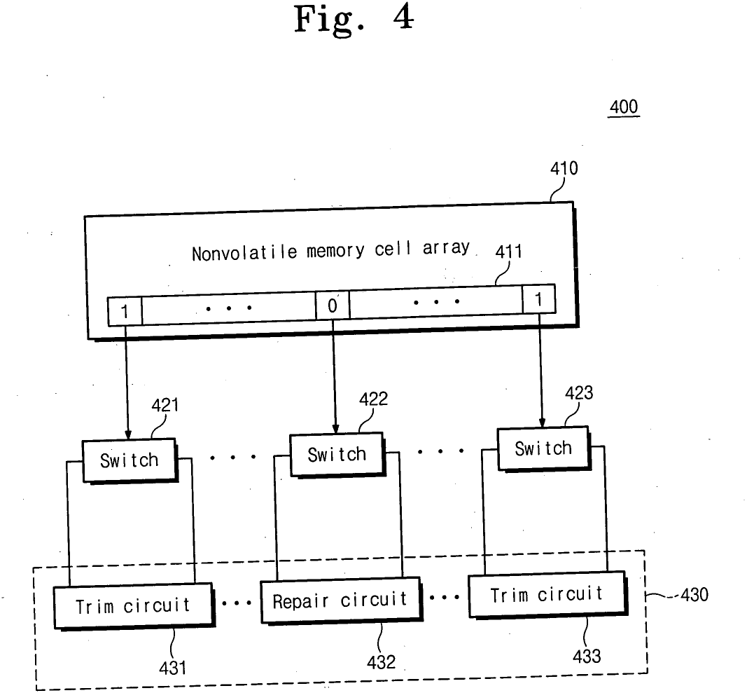

FIG. 3 is a block diagram showing an embodiment of a fuse-free semiconductor device, for example an integrated circuit (IC), 300 according to the inventive principles of this patent disclosure. Although the fuse-free semiconductor device 300 does not use a fuse, it can obtain the same effect when the fuse is used. With reference to FIG. 3, the fuse-free semiconductor IC 300 includes a non-volatile memory device 310, a volatile memory device 320, and a non-memory device 330.

The non-volatile memory device 310 stores fuse information in a memory cell. The fuse information stored in the non-volatile memory device 310 is retained even when its power supply is interrupted. The fuse information may be output from the non-volatile memory cell, for example, at a power-up.

When the power supply is interrupted, the volatile memory device 320, for example, DRAM or SRAM loses data stored therein. In addition to the memory devices, the non-memory device 330 is integrated in the semiconductor IC 300. The volatile memory device 320 and/or the non-memory device 330 may include switches 321 and 331 and adjustable circuits 322 and 332.

The switches 321 and 331 are turned on or off electrically in response to fuse information output from the non-volatile memory device 310. The on and off operations of the switches 321 and 331 emulate No_Cut and Cut operations of a fuse, respectively.

The adjustable circuits 322 and 332 may, for example, adjust a voltage to a target level or adjust an address of a defective memory cell in response to the on or off operation of the switches 321 and 331. Each of the adjustable circuits 322 and 332 may include a trim circuit or a repair circuit. For example, a trim circuit can be used to adjust a voltage generator that generates a DC voltage at a constant level. In place of a laser fuse, switches 321 and 331 may be turned on or off in response to the fuse information, thereby adjusting the output voltage of the DC voltage generator to the target voltage. As another example, the adjustable circuit 322 can include or be part of a repair circuit included in a semiconductor memory device such as a DRAM or an SRAM. The repair circuit may be used to substitute a redundancy cell for a defective cell. The defective memory cell may be substituted by using the switch 321 that is turned on or off according to the fuse information.

In the embodiment, semiconductor IC 330 may be a NAND flash memory with a NOR interface such as Samsung's OneNAND® flash device. A NAND flash memory with a NOR interface may include a non-volatile memory device such as a NAND-type memory device, a volatile memory device such as an SRAM, and a non-memory device such as a register.

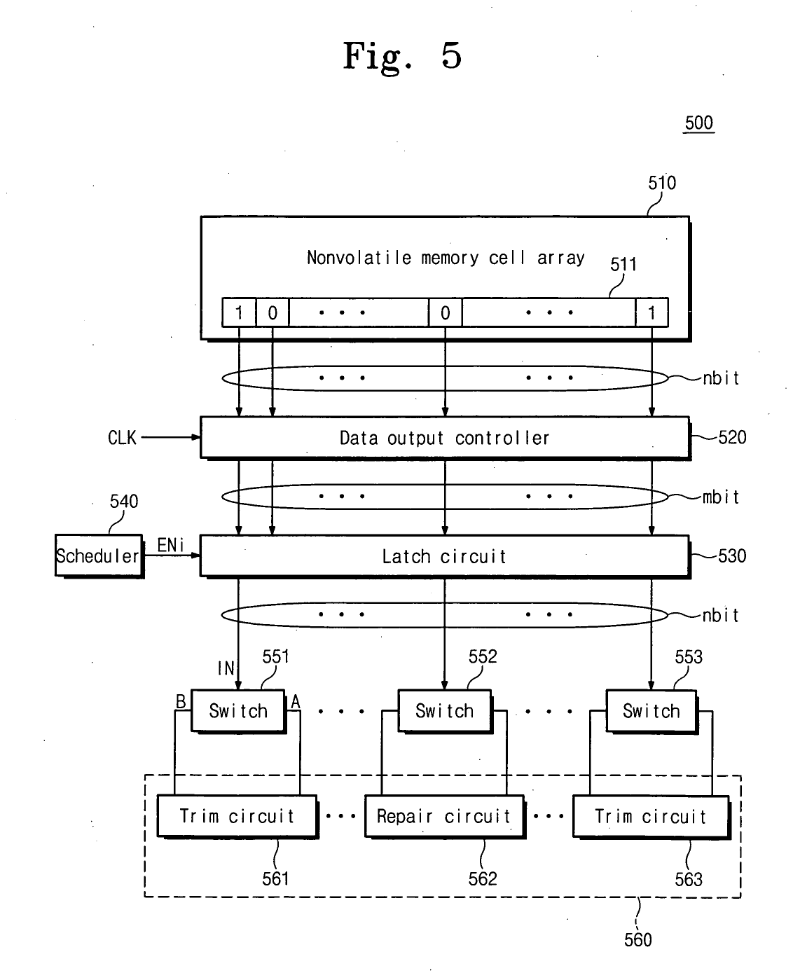

FIG. 4 is a block diagram showing an embodiment of a fuse-free non-volatile memory device according to the inventive principles of this patent disclosure. The fuse-free non-volatile memory device 400 includes a memory cell array 410, switches 421, 422 and 423, and an internal adjustable circuit 430.

The memory cell array 410 stores fuse information at a specific location defined by a security block. The memory cell array 410 is divided into a storage area that is accessible by a general user, and a specific area that is not accessible to the general user. The security block is not accessible to the user, and is a specific area (e.g., CDROW block or OTP block in a flash memory device) that the manufacturer uses.

The switches 421, 422 and 423 are electrically turned on or off according to the fuse information output from the security block 411 of the fuse-free non-volatile memory device 410. The on and off operations of the switches 421, 422 and 423 correspond to No_Cut and Cut operations of a fuse, respectively.

The internal adjustable circuit 430 is connected to both terminals of the switches 421, 422 and 423. According to on or off operation of the switches 421, 422 and 423, the internal adjustable circuit 430 provides the same results as No_Cut or Cut operations of a fuse. The internal adjustable circuit 430 includes trim circuits 431 and 433, and a repair circuit 432. The trim circuits 431 and 433 adjust a voltage level to the target value. The repair circuit 432 substitutes a redundant memory cell for a defective memory.

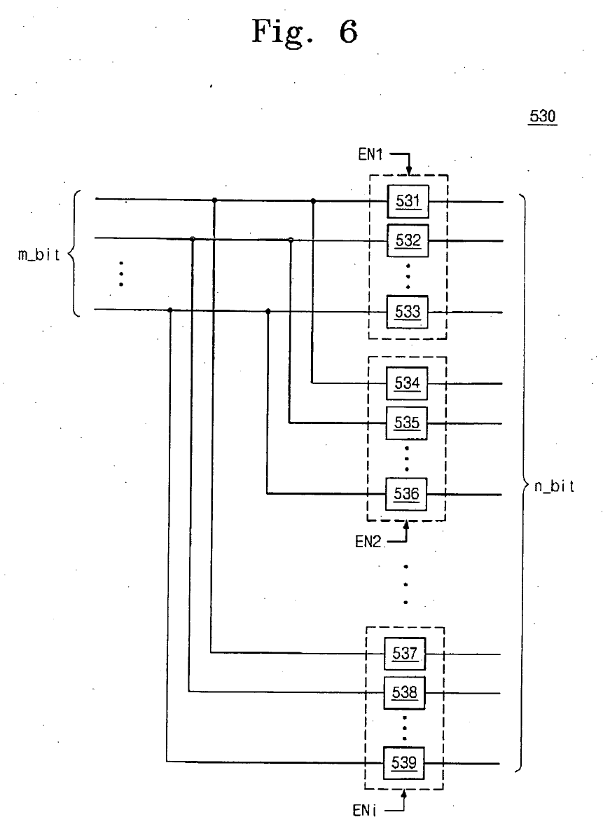

FIG. 5 is a block diagram showing another embodiment of a fuse-free non-volatile memory device 500 according to the inventive principles of this patent disclosure. The fuse-free non-volatile memory device 500 of FIG. 5 includes a memory cell array 510, a data output controller 520, a latch circuit 530, a scheduler 540, switches 551, 552 and 553, and an internal adjustable circuit 560. The memory cell array 510, switches 551, 552 and 553, and an internal adjustable circuit 560 may have the same construction and operation as those of corresponding elements of FIG. 4.

The data output controller 520 receives n bits of fuse information (where n is a positive integer) from a security block 511 of the memory cell array 510, and outputs the n bits of fuse information in m bit units (where m is a positive integer) in response to a clock signal. For example, the data output controller 520 may receive 2¹⁰ bits of fuse information, namely 1024 bits, and outputs the fuse information in 10 bit units.

The data output controller 520 may receive the n bits of fuse information from the memory cell array 510, for example, at power-up. Upon reading boot code stored in a memory cell array of a NAND-type flash memory device, the data output controller 520 may also or alternatively receive the fuse information the memory cell array between the time a power-on reset (POR) signal is applied, and the starting time of a boot code reading operation.

The data output controller 520 may simultaneously receive the n bits of fuse information from the memory cell array 510. For example, when the fuse information is stored in a page of a NAND-type flash memory device, the data output controller 520 simultaneously receives the n bits of fuse information through a read operation.

The data output controller 520 is also used to output data stored in a storage area that has been provided to a general user during normal operation.

The latch circuit 530 may receive the n bits of fuse information from the data output controller 520 in m bit units in response to a latch enable signal ENi (where i is an integer), and latch the fuse information. The scheduler 540 sequentially activates the latch enable signal ENi, whereby the latch circuit 530 receives the n bits of fuse information in m bit units.

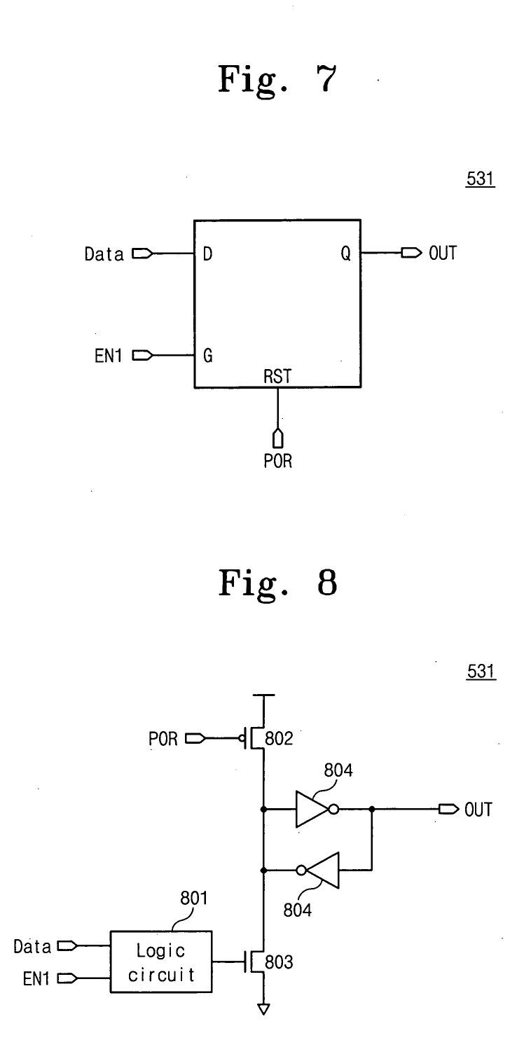

The construction and operation of some example embodiments of latch circuits according to the inventive principles of this patent disclosure will be now described by reference to FIGS. 6 to 8.

FIG. 6 is a block diagram showing an embodiment of an example latch circuit according to the inventive principles of this patent disclosure suitable for use as the latch circuit 530 shown in FIG. 5. Referring to FIG. 6, the latch circuit 530 receives fuse information in m bit units in response to latch enable signals ENi. When the first latch enable signal EN1 is activated, m bits of fuse information are latched in m latch circuits 531, 532, . . . , 533. Next, when the second latch enable signal EN2 is activated, m bits of fuse information are latched in m latch circuits 534, 535, . . . , 536. By repeating such operations, the fuse information for all n bits is latched in the latch circuit 530.

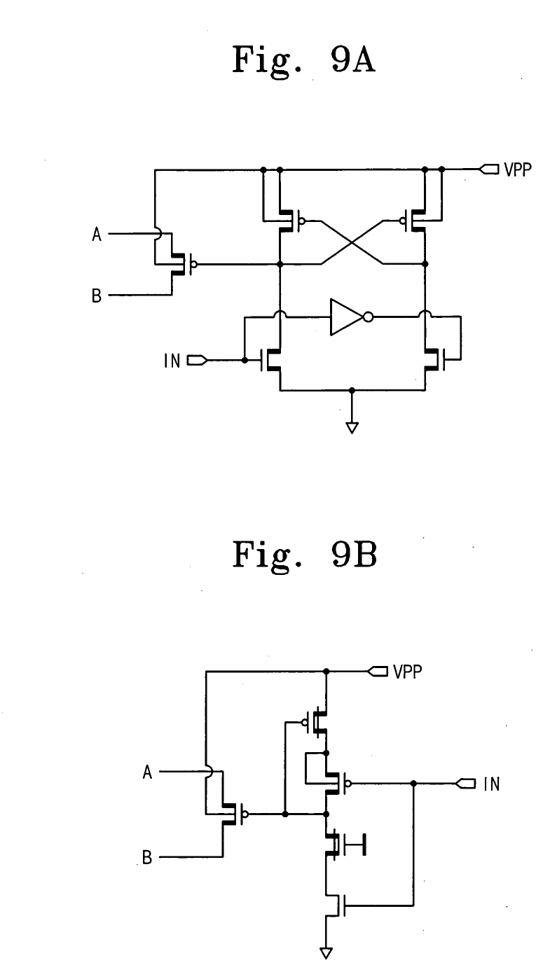

FIG. 7 illustrates an example embodiment of one latch circuit 531 shown in FIG. 7. The latch circuit 531 includes a reset terminal RST that may be initialized in response to a power-on reset signal POR, a data input terminal D for receiving fuse information, a control terminal G for receiving a latch enable signal EN1, and an output terminal Q for outputting the fuse information in response to the latch enable signal EN1.

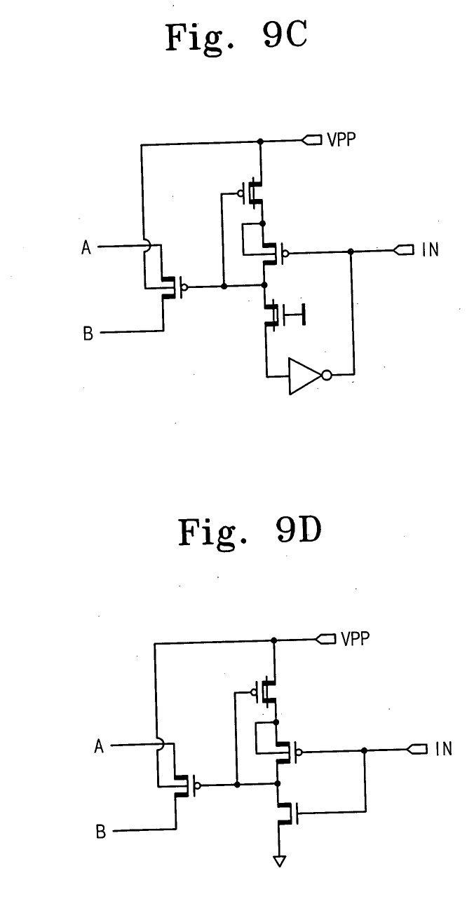

FIG. 8 is a circuit diagram showing an example embodiment of the latch circuit 531 shown in FIG. 7. With reference to FIG. 8, the latch circuit 531 includes a logic circuit 801 for receiving fuse information Data and a latch enable signal EN1, a PMOS transistor 802 for receiving a power-on reset signal POR, an NMOS transistor 803 for receiving an output value from the logic circuit 801, and inverters 804 and 805.

The latch circuit 531 initializes a latch in response to the power-on reset signal POR. That is, the output of the latch circuit 531 becomes a logic value ‘0.’ While the fuse information data is being input, the latch enable signal EN1 is activated, and the NMOS transistor is turned-on, thereby causing the latch circuit 531 to store the fuse information data which is accessible at the output terminal thereof. In an example embodiment, the logic circuit may include one AND gate.

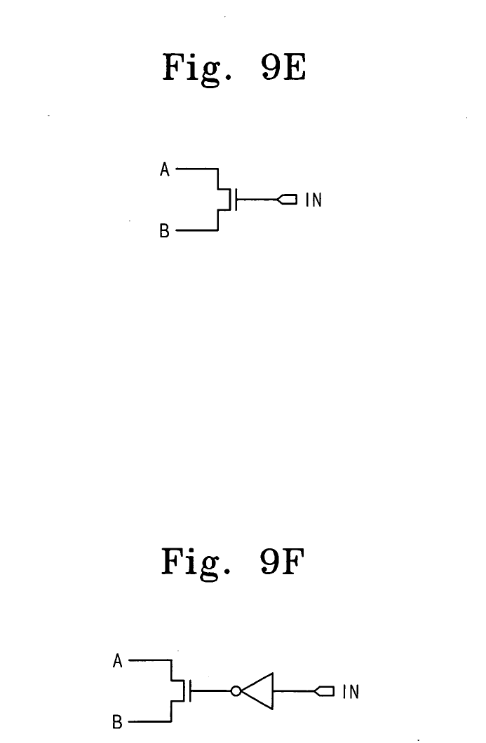

FIGS. 9A through 9F are circuit diagrams showing example embodiments of switches according to the inventive principles of this patent disclosure suitable for use as the switch shown in FIG. 5.

Each switch shown in FIGS. 9A to 9D is a high voltage level shifter that may be used in a high voltage DC trim circuit. For example, assuming a DC voltage generator operates at a voltage VPP that is higher than a power supply voltage VCC, the switch should preferably be easily turned on or off even in the presence of high voltages. Furthermore, the switch should preferably transfer high voltage input from a node A to a node B without loss. Accordingly, high voltage level shifter may be used as or with the switches. However, a higher voltage switch according to the inventive principles of this patent disclosure is not limited to a high voltage level shifter, but for example, all kinds of switches capable of operating at high voltages are applicable.

Switches shown in FIGS. 9E and 9F are examples of lower voltage switches that may be used at voltages lower than the power supply voltage VCC. For example, assuming a DC voltage generator operates at a voltage lower than the power supply voltage VCC, the lower voltage switch should preferably transfer an input voltage from a node A to a node B without loss. Some switches capable of transferring signals from a node A to a node B without loss are applicable as lower voltage switch according to the inventive principles of this patent disclosure.

In accordance with the inventive principles of this patent disclosure, problems with fuse-free circuits, fuse-free semiconductor ICs, non-volatile memory devices, and fuse-free methods, may be solved. For example, a mask for a laser fuse may be unnecessary. Second, the limitations in reducing the size of laser fuses may be overcome. Third, an EDS testing procedure and testing equipment for cutting laser fuses may be unnecessary. Fourth, even after mounting in a package, fuse information may be easily varied. Fifth, non-volatile memory cells storing fuse information may be reprogrammed, unlike a fuse which cannot be reprogrammed once it is cut.

Although the inventive principles of this patent disclosure have been described in connection with embodiments illustrated in the accompanying drawings, the inventive principles are not limited thereto. It will be apparent to those skilled in the art that various substitution, modifications and changes may be thereto without departing from the inventive principles.

1. A fuse-free circuit comprising:
a NAND flash memory cell; and
a switch to turn on or off in response to data stored in the NAND flash memory cell.

2. The fuse-free circuit as set forth in claim 1, wherein the NAND flash memory cell stores fuse information.

3. A fuse-free semiconductor device comprising:
a NAND flash memory device to store fuse information;
a switch to turn on or off electrically in response to the fuse information; and
an adjustable circuit coupled to the switch.

4. The fuse-free semiconductor device as set forth in claim 3, wherein the adjustable circuit is structured to emulate the No_Cut or Cut operation of a fuse in response to the on or off state of the switch.

5. The fuse-free semiconductor device as set forth in claim 3, further comprising a volatile memory device integrated on the same semiconductor device as the switch and the adjustable circuit.

6. The fuse-free semiconductor device as set forth in claim 5, wherein the volatile memory device comprises an SRAM.

7. The fuse-free semiconductor device as set forth in claim 4, wherein the switch and the adjustable circuit are included in a non-memory device.

8. The fuse-free semiconductor device as set forth in claim 4, wherein the adjustable circuit comprises a trim circuit to adjust a voltage to a target level.

9. The fuse-free semiconductor device as set forth in claim 4, wherein the adjustable circuit comprises a repair circuit for changing information stored in a defective memory cell.

10. The fuse-free semiconductor device as set forth in claim 4, wherein the fuse-free semiconductor device comprises a NAND flash memory with a NOR interface.

11. A fuse-free non-volatile memory device comprising:
a non-volatile memory cell array to store fuse information;
a switch to be turned on or off electrically in response to the fuse information; and
an internal adjustable circuit coupled to both ends of the switch.

12. The fuse-free non-volatile memory device as set forth in claim 11, wherein the internal adjustable circuit is structured to emulate the No_Cut or Cut operation of a fuse in response to the on or off state of the switch.

13. The fuse-free non-volatile memory device as set forth in claim 11, wherein the fuse information is stored in a security block of the memory cell array.

14. The fuse-free non-volatile memory device as set forth in claim 11, wherein the internal adjustable circuit comprises a trim circuit to adjust a voltage to a target level.

15. The fuse-free non-volatile memory device as set forth in claim 11, wherein the internal adjustable circuit comprises a repair circuit for a defective memory cell.

16. The fuse-free non-volatile memory device as set forth in claim 11, wherein the internal adjustable circuit comprises a repair circuit for changing a column address or a row address of a defective memory cell.

17. The fuse-free non-volatile memory device as set forth in claim 11, further comprising:
a data output controller to receive the fuse information from the memory cell array and output the fuse information in response to a clock signal; and
a latch circuit to receive and latch the fuse information from the data output controller and fuse information and apply the fuse information to the switch.

18. The fuse-free non-volatile memory device as set forth in claim 17, wherein the data output controller is structured to receive n bits of fuse information from the memory cell array and output the fuse information in units of m bits to the latch circuit.

19. The fuse-free non-volatile memory device as set forth in claim 18, and comprising n switches to operate in response to the n bits of fuse information.

20. The fuse-free non-volatile memory device as set forth in claim 18, further comprising a scheduler to sequentially activate a latch enable signal so that the latch circuit receives the n bits of fuse information in m bit units.

21. The fuse-free non-volatile memory device as set forth in claim 18, wherein the data output controller receives the n bits of fuse information from the memory cell array simultaneously.

22. The fuse-free non-volatile memory device as set forth in claim 17, wherein the data output controller outputs fuse information in synchronism with a transition of the clock signal.

23. The fuse-free non-volatile memory device as set forth in claim 17, wherein the data output controller receives the fuse information from the memory cell array at a power-up.

24. The fuse-free non-volatile memory device as set forth in claim 23, wherein the data output controller outputs normal data stored in the memory cell array during a normal operation.

25. The fuse-free non-volatile memory device as set forth in claim 18, wherein the data output controller receives n bits of fuse information from the memory cell array between the time a power-on reset signal is applied, and the time a boot code reading operation starts.

26. The fuse-free non-volatile memory device as set forth in claim 25, wherein the latch circuit is initialized in response to the power-on reset signal.

27. The fuse-free non-volatile memory device as set forth in claim 18, wherein n is 2^{m}.

28. The fuse-free non-volatile memory device as set forth in claim 17, wherein the fuse-free non-volatile memory device comprises a NAND-type flash memory device.

29. A method comprising:
storing fuse information in a NAND flash memory cell;
electrically turning a switch on or off in response to the fuse information; and
emulating the No_Cut or Cut operation of a fuse in response to the on or off state of the switch.

30. The method as set forth in claim 29, wherein emulating the operation of a fuse includes adjusting a voltage to a target level in response to turning the switch on or off.

31. The method as set forth in claim 29, wherein emulating the operation of a fuse includes changing a column address or a row address of a defective memory cell in response to turning the switch on or off.
